(19) United States
(12) Patent Application Publication
(10) Pub. No.: US 2010/0102859 A1
(43) Pub. Date: Apr. 29, 2010

(54) LC VOLTAGE CONTROLLED OSCILLATOR TANK WITH LINEARIZED FREQUENCY CONTROL

(75) Inventor: JOHN WILLIAM FATTARUSO, DALLAS, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/260,699

(22) Filed: Oct. 29, 2008

(51) Int. Cl. H03L 7/099; H03B 5/12

(52) U.S. Cl. 327/157; 331/117 FE

(57) ABSTRACT

Over the past few decades, phased locked loops or PLLs have become increasingly common in a variety of microelectronic applications. As such, the PLLs have both decreased in size and increased in speed, following the same trend as all other microelectronics. With this change in size and speed, alternative designs for voltage controlled oscillator tanks or VCOs (and other components of PLLs) are being developed. Here, an LC VCO with a correction circuit (for linearizing the frequency versus control voltage characteristics of the VCO) is described that can allow a small and fast PLL to remain generally stable over a wide range of frequencies.

### TECHNICAL FIELD

The invention relates generally to voltage controlled oscillator tanks (VCO) and, more particularly, to LC VCOs.

### BACKGROUND

Over the years, phased locked loops or PLLs have become increasingly common as frequency synthesizers and clock generators. As a matter of fact, there are a variety of different applications that employ PLLs, such as DRAM. In many these applications, though, clock ranges can be very large, requiring the VCOs contained with the PLLs to be tunable over a very large range. In addition to having tunability over a wide range, there may also be a need for low phase noise, which is generally accomplished through the use high-Q LC VCOs.

In order to have the desired tunability and low phase noise, so-called LC VCOs are typically employed. In these LC VCOs, the oscillator tank of the VCO generally includes two groups of capacitive elements (a bank of digitally selectable elements and a continuous frequency control element), so that, in operation, the approximate target frequency can be selected by the bank while the continuous frequency control element allows the PLL to settle on a particular frequency. Some examples of LC VCOs are discussed in the following articles: Soltanian et al., “An Ultra-Compact Differentially Tuned 6-GHz CMOS LC-VCO With Dynamic Common Mode Feedback”, IEEE Journal of Solid State Circuits, 42(8), August 2007, pgs. 1635-1641; Stasewski et al., “A Digitally Controlled Oscillator tank in a 90 nm Digital CMOS Process for Mobile Phones”, IEEE Journal of Solid State Circuits, 40(11), November 2007, pgs. 2203-2211; and Perrott et al., “A 2.5-Gb/s Multi-Rate 0.25-μm CMOS clock and Data Recover Circuit Utilizing a Hybrid Analog/Digital Loop filter and All-Digital Referenceless Frequency Acquisition”, IEEE Journal of Solid State Circuits, 41(12), December 2006, pgs. 2930-2944. Some additional designs for VCOs can be found in the following U.S. Patent Numbers and U.S. Pre-Grant Publication Numbers: U.S. Pat. Nos. 6,658,748; 7,133,485; 7,301,407; 7,385,452; 2002/0008593; 2003/0107442; 2003/0133522; 2003/0141936; 2005/0212609; 2005/0212614; and 2007/0057736.

However, in the design of a feedback loop of a PLL, one factor that is considered is the rate of change or slope of nonlinear frequency versus control voltage of the VCO or k_{VCO}. Often pole and zero locations in the loop compensation network are chosen for a damping factor to accommodate a particular incremental value of k_{VCO} around an operating point. Normal variances in manufacturing as well as other factors, though, contribute to variability in this gain factor, which may a practical PLL more difficult to design and manufacture.

Therefore, there is a need for a method and/or apparatus to reduce the variation in k_{VCO} in a desired frequency range.

### SUMMARY

A preferred embodiment of the present invention, accordingly, provides an apparatus. The apparatus includes an oscillator tank that is adapted to receive a plurality of digital selection signals and an analog control signal and a gain circuit coupled to the oscillator tank. The oscillator tank further includes an inductor, a selection network having a first set of capacitive elements coupled in parallel to the inductor, wherein the selection network receives the digital selection signals and incrementally varies the capacitance of the oscillator tank, a capacitive network coupled in parallel to the inductor, the capacitive network receiving at least one analog control signal, and a correction network coupled in parallel to the inductor, the correction network having a second set of capacitive elements coupled in series with one another, and the correction network receiving the analog control signal at a node between at least two of the capacitive elements in the second set of capacitive elements.

In accordance with another preferred embodiment of the present invention, each of the first and second sets of capacitive elements further comprise Accumulation MOS (AMOS) capacitors.

In accordance with another preferred embodiment of the present invention, the capacitive network further comprises a plurality of PN junction varactors coupled in series with one another, wherein the analog control signal is received at a node between at least two of the PN junction varactors.

In accordance with another preferred embodiment of the present invention, the selection network has a plurality of branches, each branch further comprises a plurality of AMOS capacitors coupled in series to one another, and a node between at least two AMOS capacitors that receives at least one of the digital selection signals.

In accordance with another preferred embodiment of the present invention, the gain circuit further comprises two pairs of cross-coupled FETs.

In accordance with another preferred embodiment of the present invention, at least one pair of cross-coupled FETs is coupled to a first voltage rail.

In accordance with another preferred embodiment of the present invention, a current mirror that is coupled to at least one of the pairs of cross coupled FETs.

In accordance with another preferred embodiment of the present invention, the current mirror, the capacitive network, and the correction network are coupled to a second voltage rail.

In accordance with another preferred embodiment of the present invention, a VCO is provided. The VCO comprises a first voltage rail, a first pair of cross-coupled FETs coupled to the first voltage rail, a second pair of cross-coupled FETs, an inductor coupled to each drain of the first pair of cross-coupled FETs and coupled to each drain of the second pair of cross-coupled FETs, a selection network having a plurality of branches that are coupled in parallel to the inductor, a capacitive network coupled in parallel to the inductor, and a correction network coupled in parallel to the inductor. Each branch of the selection network includes at least two first sets of binarily weighted capacitive elements coupled in series with one another and a first node between the two first sets of capacitive elements that receives a digital selection signal. The capacitive network has at least two second sets of capacitive elements coupled to one another and a second node between the two second sets of capacitive elements that receives an analog control signal. Additionally, the correction network has at least two third set of capacitive elements coupled in series with one another, and a third node between the two third sets of capacitive elements that is coupled to second node.

In accordance with another preferred embodiment of the present invention a PLL. The PLL comprises a phase/frequency detector (PFD) that is adapted to receive a reference signal, a charge pump that receives an output signal from the PFD, a filter that receives an output signal from the charge pump, and a VCO receives an output signal from the filter, a plurality of digital selection signals, and an analog control signal. The VCO includes an oscillator tank that is adapted to receive a plurality of digital selection signals and an analog control signal. The oscillator tank further includes an inductor, a selection network having a first set of capacitive elements coupled in parallel to the inductor, wherein the selection network receives the digital selection signals and incrementally varies the capacitance of the oscillator tank, a capacitive network coupled in parallel to the inductor, the capacitive network receiving at least one analog control signal, and a correction network coupled in parallel to the inductor, the correction network having a second set of capacitive elements coupled in series with one another, and the correction network receiving the analog control signal at a node between at least two of the capacitive elements in the second set of capacitive elements, and a gain circuit coupled to the inductor.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a PLL in accordance with a preferred embodiment of the present invention;

FIG. 2 is VCO in accordance with a preferred embodiment of the present invention; and

FIG. 3 is a graph depicting the frequency versus control voltage of FIG. 2.

### DETAILED DESCRIPTION

Refer now to the drawings wherein depicted elements are, for the sake of clarity, not necessarily shown to scale and wherein like or similar elements are designated by the same reference numeral through the several views.

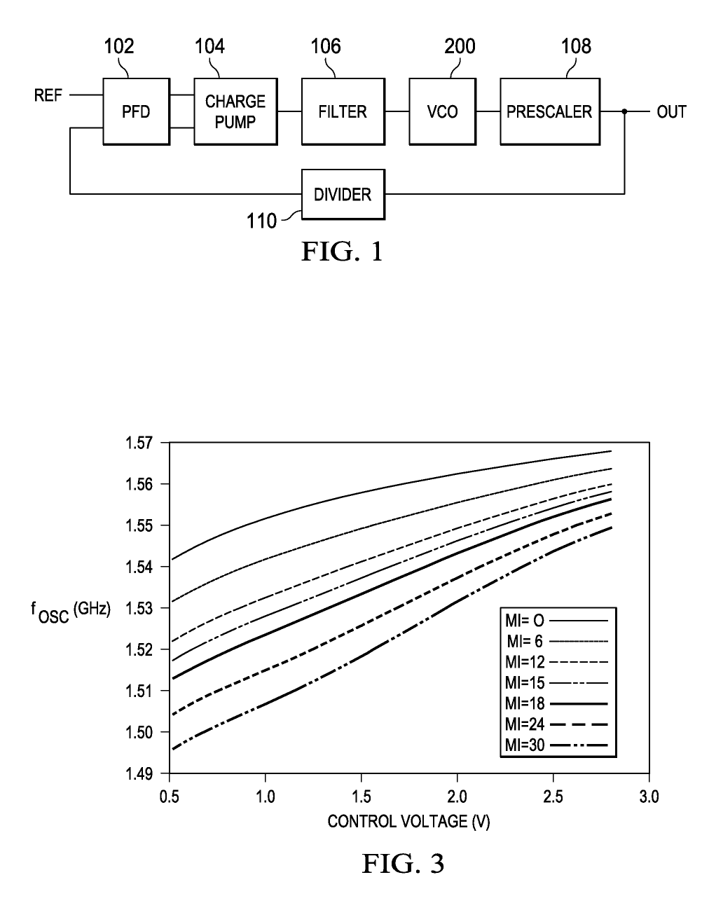

Referring to FIG. 1 of the drawings, reference numeral 100 generally designates a phased locked loop (PLL) in accordance with a preferred embodiment of the present invention. The PLL 100 can have a frequency range from about 500 Mhz to about 1 GHz and may comprises a PFD 102, a charge pump 104, a filter 106, a VCO 200, a prescaler 108, and a divider 110. As with many prior art designs, the PFD 102 compares a reference signal to a divided signal. The output of the PFD 102 is fed to a charge pump 104 and filtered by filter 106 so that a voltage level or value can be input into the VCO 200, where an output signal is generated. Theoretically, the frequency of the output signal of the VCO 200 is proportional to the input voltage. Additionally, the output of the VCO 200 is then divided or scaled down by prescaler 108 (which is typically a divide by two or divide by three prescaler) and divider 110. This output signal is then fed back to the PFD 102.

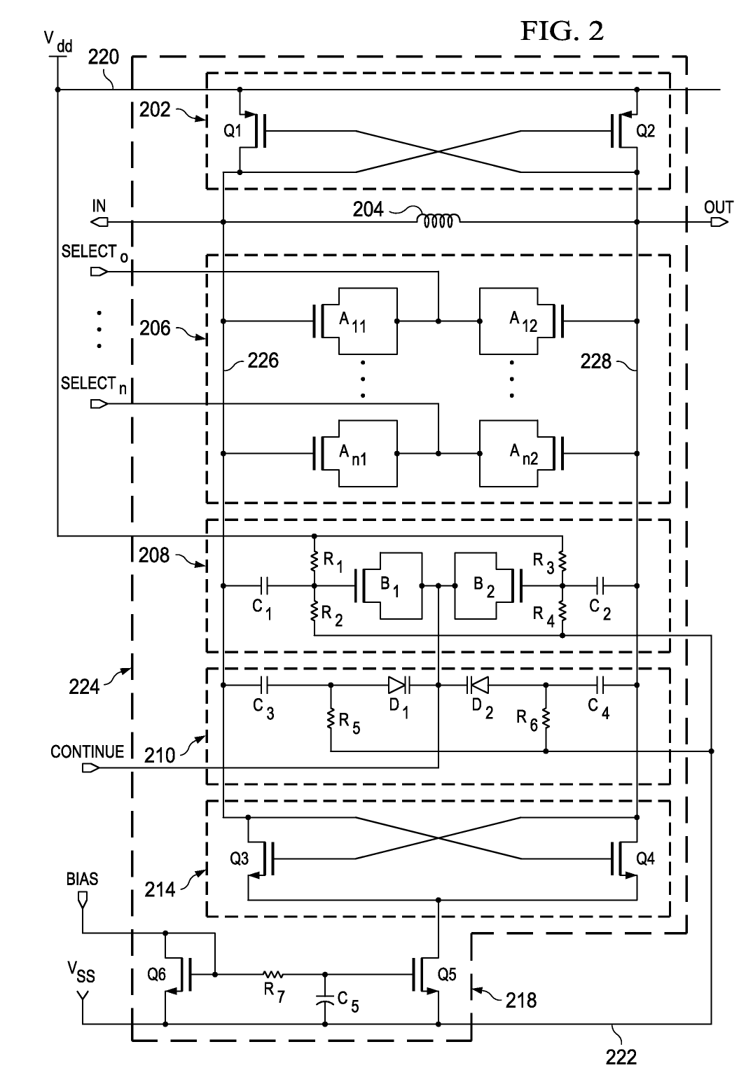

One difference between PLL 100 and other prior art designs is the VCO 200. VCO 200, which is depicted in greater detail in FIG. 2 of the drawings, is an LC VCO. Specifically, VCO 200 can be subdivided into several major subassemblies: the differential gain cell 202 and 214; the oscillator tank circuit 224; and the current mirror 218.

First looking to the differential gain cell 202 and 214, it operates to assist in overcoming the resonant losses in the oscillator tank 224 and helps to ensure a startup of oscillations. Preferably, the gain cell 202 and 214 is comprised of two pairs of cross-coupled CMOS FETs with the oscillator tank 224 interposed therebetween. With the first pair of cross-coupled FETs 202, the sources of FETs Q1 and Q2 are preferably coupled to the first voltage rail 220 (V_{dd}), while the gates of each of FETs Q1 and Q2 are preferably coupled to the other's drain at nodes 226 and 228. With the second pair of cross-coupled FETs 214, the drain of FET Q3 and the gate of FET Q4 are coupled to node 226, while the drain of FET Q4 and the gate of FET Q3 are coupled to node 228. Finally, the sources of FETs Q3 and Q4 are coupled to the current mirror 218.

The current mirror 218 provides a well-controlled biasing current for the gain cell 202 and 214. Preferably, FET Q5 is interposed between the second pair of cross-coupled FETs 214 and the second rail 222, where its drain is coupled to the sources of FETs Q3 and Q4 and its source is coupled to the second rail 222. The gate of FET Q5 is preferably coupled to the second rail 222 through capacitor C₅ as well as the base of FET Q7 (through resistor R₇). The resistor R₇ and capacitor C₅ generally filter noise at FET Q5 to help limit oscillator tank phase noise. Additionally, the biasing current IBIAS is fed to the drain and gate of FET Q5, while the source is coupled to the second rail 222.

The oscillator tank 224, which again is interposed between the two pairs of cross-coupled FETs 202 and 204, is generally comprised of an inductor 204 and capacitive elements. The inductor 204 is typically about 2.3 nH, and the total capacitance can be from about 2.7 pF to about 6 pF. Preferably, the capacitive elements of the oscillator tank 224 are arranged in several groups: selection network 206; capacitive network 210; and correction network 208.

The selection network 206 generally operates to digitally tune the VCO 200 to an approximate target frequency. In particular, the selection network 206 is preferably comprised of several branches that are electrically coupled in parallel to the inductor 204, where the number of branches would depend on the desired range of the VCO 200. Typically, the selection network 206 has 6 branches. Each of the branches is preferably comprised of a plurality of AMOS capacitors coupled to in series to one another that are binarily weighted. Each branch, for the sake of simplicity, is shown in FIG. 3 as having two AMOS capacitors (A₁₁/A₁₂ through Aₙ₁/Aₙ₂). Preferably, each AMOS capacitor shown (A₁₁/A₁₂ through Aₙ₁/Aₙ₂) is comprised of a number of “unit” capacitors coupled in parallel with one another, where the number of unit capacitors is an integer power of two. At the node between the sets of binarily weighted AMOS capacitors, each branch can receive a digital selection signal (SELECT₀ through SELECTₙ) at the substrate terminals of the AMOS capacitors bordering the middle node, which is shown as between the two AMOS capacitors (A₁₁/A₁₂ through Aₙ₁/Aₙ₂) on each branch in FIG. 3, so that when a select signal is received the capacitance of the oscillator tank 224 can be incrementally increased or varied to approximate a desired, target frequency.

The capacitive network 210 generally operates to allow a PLL to settle on a particular frequency or provide “fine tuning.” Preferably, the capacitive network 210 is comprised of a single branch that is electrically coupled in parallel to the inductor 204 and the branches of the selection network 206. As with the selection network 206, the capacitive network 210 includes a pair of capacitive elements for each branch. As illustrated, within the branch of the capacitive network 210, there are two capacitors C₃ and C₄ and two PN junction varactor diodes D₁ and D₂ coupled in series to one another, where each varactor diodes D₁ and D₂, preferably, has a capacitance of about 200 fF. Each of the capacitors C₃ and C₄ is preferably coupled to the inductor 204 and to the anode of one of varactor diodes D₁ and D₂ (operating as coupling capacitors). The cathodes of the varactor diodes D₁ and D₂ are preferably coupled to one another at a node that receives an analog control signal CONT. Additionally, resistors R₅ and R₆ are preferably coupled to the anodes of varactor diodes D₁ and D₂ to establish a DC bias voltage at the second voltage rail 222.

The correction network 208 operates to assist in linearizing the frequency versus control voltage of the VCO. Preferably, the correction network 208 is comprised of a single branch that is electrically coupled in parallel to the inductor 204. As with both the selection network 206 and the capacitive network 210, each branch of the correction network 208 preferably includes a pair of capacitive elements. As illustrated, though, the branch of the correction networks includes two capacitors C₁ and C₂ and two AMOS capacitors B₁ and B₂ coupled in series with one another. The capacitors C₁ and C₂ operate as coupling capacitors, similar to capacitors C₃ and C₄, with the two AMOS capacitors B₁ and B₂ interposed therebetween. Preferably, the substrate terminals of AMOS capacitors B₁ and B₂ are coupled together at a node that also receives the analog control voltage CONT. Additionally, each gate of the two AMOS capacitors B₁ and B₂ is preferably coupled to one voltage dividers (R₁/R₂ and R₃/R₄), where each voltage divider is coupled to the first voltage rail 220 and second voltage rail 222 so to provide an appropriate bias level. Specifically, this bias level should be should be sufficient to allow for oscillation voltage excursions to exercise the AMOS capacitors B₁ and B₂ symmetrically about the center of the capacitance range of VCO 200 when the VCO 200 is at the center of its design range. Moreover, each AMOS capacitor B₁ and B₂ is generally comprised of one or more unit capacitors, where the total capacitance of the correction network 208 is preferably about 100 fF.

Under the circumstances where the correction network 208 is missing or where the value of the AMOS capacitors B₁ and B₂ are 0 (as shown in the curve labeled mi=0 of FIG. 3), the VCO 200 would experience a nonlinear frequency versus control voltage. As can be seen in FIG. 2, the anodes of varactor diodes D₁ and D₂ would be at an average DC level of the voltage of the second rail 222 or Vₛₛ. This DC level of the anodes of varactor diodes D₁ and D₂ in conjunction with the nonlinear behavior of the FETs Q₁, Q₂, Q₃, and Q₄ would mean that varactor diodes D₁ and D₂ would be reverse bias through oscillation voltage excursions. Thus, the square root relationship between capacitance and bias voltage varactor diodes D₁ and D₂ would be particularly influential to the operation of the VCO 200, causing the VCO 200 to experience a nonlinear frequency versus control voltage.

When the sizes of AMOS capacitors B₁ and B₂ are increased, though, frequency versus control voltage can be linearized. AMOS capacitors, such as the AMOS capacitors B₁ and B₂, generally exhibit strong nonlinear capacitance so a small fraction of the varactor diodes D₁ and D₂ would be used for AMOS capacitors B₁ and B₂ to linearize the VCO 200. Additionally, if the capacitances of AMOS capacitors B₁ and B₂ are too large in relation to the varactor diodes D₁ and D₂, the phase noise performance of the VCO 200 can also be degraded. This linearization can be seen in FIG. 3, where the capacitive values of the AMOS capacitors B₁ and B₂ are increased.

As can be seen in FIG. 3, the frequency versus control voltage for different values of the AMOS capacitors B₁ and B₂ are shown, ranging incrementally from mi=0 to mi=30, where “mi” denotes integer units of unit AMOS capacitors in parallel. Of these curves shown in FIG. 3, the curve for mi=15 or 15 unit capacitors is approximately linear. This linearization, therefore, can make the behavior of PLL much more uniform over its voltage control range. Moreover, the frequency range that may be swept by the analog control voltage can be increased, which may be advantageous in PLL designs where the temperature dependence of the VCO components is to be absorbed into the PLL loop capture range.

Having thus described the present invention by reference to certain of its preferred embodiments, it is noted that the embodiments disclosed are illustrative rather than limiting in nature and that a wide range of variations, modifications, changes, and substitutions are contemplated in the foregoing disclosure and, in some instances, some features of the present invention may be employed without a corresponding use of the other features. Accordingly, it is appropriate that the appended claims be construed broadly and in a manner consistent with the scope of the invention.

1. An apparatus comprising:
an oscillator tank that is adapted to receive a plurality of digital selection signals, and an analog control signal, the oscillator tank including:
an inductor;
a selection network having a first set of capacitive elements coupled in parallel to the inductor, wherein the selection network receives the digital selection signals and incrementally varies the capacitance of the oscillator tank;
a capacitive network coupled in parallel to the inductor, the capacitive network receiving at least one analog control signal; and
a correction network coupled in parallel to the inductor, the correction network having a second set of capacitive elements coupled in series with one another, and the correction network receiving the analog control signal at a node between at least two of the capacitive elements in the second set of capacitive elements; and
a gain circuit coupled to the oscillator tank.

2. The apparatus of claim 1, wherein each of the first and second sets of capacitive elements further comprise Accumulation MOS (AMOS) capacitors.

3. The apparatus of claim 2, wherein the capacitive network further comprises a plurality of PN junction varactors coupled in series with one another, wherein the analog control signal is received at a node between at least two of the PN junction varactors.

4. The apparatus of claim 1, wherein the selection network has a plurality of branches, each branch further comprises:
a plurality of AMOS capacitors coupled in series to one another; and
a node between at least two AMOS capacitors that receives at least one of the digital selection signals.

5. The apparatus of claim 1, wherein the gain circuit further comprises two pairs of cross-coupled FET.

6. The apparatus of claim 5, wherein at least one pair of cross-coupled FETs is coupled to a first voltage rail.

7. The apparatus of claim 5, wherein the apparatus further comprises a current mirror that is coupled to at least one of the pairs of cross coupled FETs.

8. The apparatus of claim 7, wherein the current mirror, the capacitive network, and the correction network are coupled to a second voltage rail.

9. A voltage controlled oscillator tank (VCO), comprising:
a first voltage rail;
a first pair of cross-coupled FETs coupled to the first voltage rail;
a second pair of cross-coupled FETs;
an inductor coupled to each drain of the first pair of cross-coupled FETs and coupled to each drain of the second pair of cross-coupled FETs;
a selection network having a plurality of branches that are coupled in parallel to the inductor, each branch including:
at least two first sets of binarily weighted capacitive elements coupled in series with one another; and
a first node between the two first sets of capacitive elements that receives a digital selection signal;
a capacitive network coupled in parallel to the inductor, the capacitive network having:
at least two sets of capacitive elements coupled to one another; and
a second node between the two second sets of capacitive elements that receives an analog control signal; and
a correction network coupled in parallel to the inductor, the correction network having:
at least two third sets of capacitive elements coupled in series with one another; and
a third node between the two third sets of capacitive elements that is coupled to second node.

10. The VCO of claim 9, wherein the first and third sets of capacitive elements are AMOS capacitors.

12. The VCO of claim 9, wherein the second set of capacitive elements are varactor diodes.

13. A phased-locked loop (PLL) comprising:
a phase/frequency detector (PFD) that is adapted to receive a reference signal;
a charge pump that receives an output signal from the PFD;
a filter that receives an output signal from the charge pump;
a VCO receives an output signal from the filter, a plurality of digital selection signals, and an analog control signal, the VCO including:
an inductor;
a selection network having a first set of capacitive elements coupled in parallel to the inductor, wherein the selection network receives the digital selection signals and incrementally varies the capacitance of the oscillator tank;
a capacitive network coupled in parallel to the inductor, the capacitive network receiving at least one analog control signal; and
a correction network coupled in parallel to the inductor, the correction network having a second set of capacitive elements coupled in series with one another, and the correction network receiving the analog control signal at a node between at least two of the capacitive elements in the second set of capacitive elements; and
a gain circuit coupled to the inductor; and
a divider that receives an output signal from the VCO and feeds a divided signal back to the PFD.

14. The apparatus of claim 13, wherein each of the first and second sets of capacitive elements further comprise AMOS capacitors.

15. The apparatus of claim 14, wherein the capacitive network further comprises a plurality of PN junction varactors coupled in series with one another, wherein the analog control signal is received at a node between at least two of the PN junction varactors.

16. The apparatus of claim 13, wherein the selection network has a plurality of branches, each branch further comprises:
a plurality of AMOS capacitors coupled in series to one another; and
a node between at least two AMOS capacitors that receives at least one of the digital selection signals.

17. The apparatus of claim 13, wherein the gain circuit further comprises two pairs of FETs.

18. The apparatus of claim 17, wherein at least one pair of cross-coupled FETs is coupled to a first voltage rail.

19. The apparatus of claim 17, wherein the apparatus further comprises a current mirror that is coupled to at least one of the pairs of cross coupled FETs.

20. The apparatus of claim 19, wherein the current mirror, the capacitive network, and the correction network are coupled to a second voltage rail.
